(19) United States
(12) Patent Application Publication
(10) Pub. No.: US 2024/0373655 A1
(43) Pub. Date: Nov. 7, 2024

(54) VOLTAGE CONTROLLED ORGANIC INVERSE PHOTO TRANSISTOR AND APPLICATIONS THEREOF

(71) Applicant: NUtech Ventures, Inc., Lincoln, NE (US)

(72) Inventors: Peter A. Dowben, Lincoln, NE (US); Esha Mishra, Lincoln, NE (US); Thilini K. Ekanayaka, Lincoln, NE (US)

(21) Appl. No.: 18/775,445

(22) Filed: Jul. 17, 2024

Related U.S. Application Data
(63) Continuation of application No. PCT/US2023/060812, filed on Jan. 18, 2023.
(60) Provisional application No. 63/300,951, filed on Jan. 19, 2022.

(51) Int. Cl. H10K 10/46; H10K 85/10; H10K 85/60

(52) U.S. Cl. CPC H10K 10/471; H10K 85/141; H10K 85/657

(57) ABSTRACT

A photoactive device, comprising a first layer comprising a polymer of formula (1) or a salt thereof, a method comprising illuminating the photoactive device, a method of making the photoactive device, and a composition comprising the polymer of formula (1) and a dye. The photoactive device operates as an inverse phototransistor in which the current is higher in the absence of illumination and lower in the presence of illumination.

### CROSS-REFERENCE TO RELATED APPLICATIONS

This application is a continuation of International Application No. PCT/US2023/60812, filed on Jan. 18, 2023, titled “VOLTAGE CONTROLLED ORGANIC INVERSE PHOTO TRANSISTOR AND APPLICATIONS THEREOF,” which claims priority to U.S. Provisional Patent Application No. 63/300,951, filed Jan. 19, 2022. All of the afore-mentioned applications are hereby incorporated by reference in their entireties.

### FEDERALLY SPONSORED RESEARCH OR DEVELOPMENT

This invention was made with Government support under DMR1827690 and OIA2044049 awarded by the National Science Foundation. The Government has certain rights in this invention.

### BACKGROUND

In recent years, organic photo-sensing devices are an attractive area of research due to their wide range of applications including organic photodetectors, organic photodiodes, organic photosensors, and organic phototransistors. The low-cost fabrication methods and ability to make changes in the properties of the material, by just varying the chemical structure makes organic electronics very appealing.

Although phototransistors are common, phototransistors that have no photocurrent enhancement but rather a decrease in the source-drain current, when exposed to light, are less common. Indeed, this sort of ‘inverse’ phototransistor is unusual and could be harnessed for a variety of useful applications.

Thus, there is a need in the art for phototransistors that have such properties.

### SUMMARY

The present embodiments provide phototransistors and in particular ‘inverse’ phototransistors.

Disclosed is a photoactive device, comprising:
a first layer comprising a polymer of formula (1):

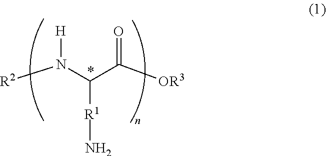

or a salt thereof;
wherein:
R¹ is a single bond or an optionally substituted C₁-C₁₀ alkyl group;
R² and R³ independently are terminating groups that can be the same or different; and
n is an integer from 10 to 10,000,
optionally further comprising at least one dye capable of generating a photoexciton when illuminated with light having a wavelength of 530 nm or less, such as methylene blue. Other organic dipolar molecular combinations may be suitable as well, including [Fe(Htrz)₂(trz)](BF₄) spin crossover plus Benzimidazole (BM).

Also disclosed is a method comprising illuminating a photoactive device with light having a wavelength of 530 nm or less.

Further disclosed is a method of making a photoactive device, comprising depositing a first layer on a substrate.

Also disclosed is a composition comprising a polymer of formula (1) and a dye capable of generating a photoexciton when illuminated with light having a wavelength of 530 nm or less, such as methylene blue, optionally wherein the polymer of formula (1) is zwitterionic.

### BRIEF DESCRIPTION OF THE DRAWINGS

FIG. 1: Schematic showing two depictions, a) and b), of the structure of poly-D-lysine

FIG. 2: Current-voltage (I-V) characteristics of a) poly-D-lysine and b) poly-D-lysine plus methylene blue as an additive. Curve 1 indicates the current at dark (no illumination) and curve 2 indicates current in light (illumination).

FIG. 3: The source to drain current transfer characteristics of a) a poly-D-lysine thin film transistor and b) a poly-D-lysine thin film transistor with methylene blue as an additive. Source to drain currents are plotted for gate voltages ranging from −15 V to +15 V at 0.1 V source voltage. Curve 1 and curve 2 indicate the drain current at dark and light, respectively.

FIG. 4: The Capacitance-voltage (C-V) characteristics of a) poly-D-lysine thin film and b) a poly-D-lysine thin film with methylene blue as an additive. Curve 1 and curve 2 indicate the capacitance at dark and light, respectively.

FIG. 5: Carrier lifetime (τ) versus voltage of a) poly-D-lysine thin film and b) a poly-D-lysine thin film with methylene blue as an additive. Curve 1 and curve 2 indicate the carrier lifetime at dark and light, respectively.

FIG. 6: Capacitance versus trial numbers with alternate cycles of dark and light of a) poly-D-lysine thin film device (on MicruX electrodes, Dark (*)(dots labeled “1”), Light (*)(dots labeled “2”)) and b) poly-D-lysine thin film device with methylene blue as an additive (on Metrohm DropSens electrodes, Dark (∘) (dots labeled “1”), Light (∘) (dots labeled “2”) and on MicruX electrodes, Dark (*)(dots labeled “1”), Light (*)(dots labeled “2”)). The capacitance value in FIG. 6 b) on Metrohm DropSens electrodes was scaled with respect to the capacitance value on MicruX electrodes.

FIG. 7: A schematic of a photoactive device structure.

### DETAILED DESCRIPTION

In some aspects, disclosed is a voltage controlled organic inverse phototransistor for various applications, including sensor applications.

In some aspects, there is a clear evidence that an organic inverse phototransistor is possible. In some aspects, disclosed are voltage-controlled changes in the electronic structure of a device comprising, e.g., poly-D-lysine and methylene blue. In some aspects, because these organic thin films are easily fabricated, and compatible with flexible substrates, there is the potential here for low cost organic inverse phototransistors. In some aspects, the low cost of materials and trivial deposition method makes it very valuable.

In some aspects, disclosed is an organic inverse phototransistor that in some aspects is cost effective and easy to fabricate. In some aspects, disclosed is a phototransistor that is the “off state” when illuminated by light and “on” when in the dark (i.e., absence of illumination). In some aspects, this is an ideal sensor and low power because it operates in the reverse sense of all other photodiodes and phototransistors. In some aspects, disclosed is a device that is ferroelectric. In some aspects, disclosed is a device made from or comprising at least a portion of biomaterials. In some aspects, a polymer (as disclosed elsewhere herein) is deposited by forming a solution and printing as an ink. In some aspects, a solution of a polymer and a dye (both of which are disclosed elsewhere herein) is prepared and then deposited by printing like an ink.

In some aspects, disclosed is a composition of matter that forms an organic phototransistor made from poly-D-lysine and methylene blue. In some aspects, this composition of matter acts as an “inverse phototransistor,” meaning that it is in the “off” state when light is present, and in the “on” state in the dark. In some aspects, disclosed is an organic inverse phototransistor comprising a polymer (e.g., a polypeptide, such as poly-D-lysine) and a dye (e.g., methylene blue) as a thin film.

In some aspects, the composition of matter and/or devices disclosed herein have various benefits, such as (1) cost effectiveness: the organic materials used to make this phototransistor are widely available and low-cost; (2) easier fabrication: the technology generally does not require a specific deposition or fabrication method; (3) green chemistry: use of organic materials allows for safer disposal and less release of toxic chemicals into the environment; (4) ferroelectric: the polymer employed herein, such as poly-D-lysine, exhibits ferroelectric properties; or (5) any combination thereof, including a combination of (1)-(4).

In some aspects, the composition(s) of matter and/or device(s) disclosed herein can be employed in any suitable application including, for example, as photoactive devices, information storage devices, memory devices, semiconductor manufacturing, inverse phototransistors, dark sensors, thin film transistors (TFTs), organic TFTs, chemical sensors, biological sensors, detectors, sensors (e.g., dark and/or light sensors), or any combination thereof.

Disclosed is a photoactive device, comprising:
a first layer comprising a polymer of formula (1):

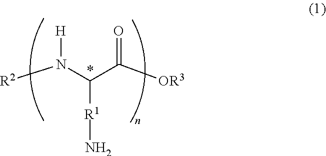

or a salt thereof;
wherein:
R¹ is a single bond or an optionally substituted C₁-C₁₀ alkyl group;
R² and R³ independently are terminating groups that can be the same or different; and
n is an integer from 10 to 10,000.

In some aspects, the photoactive device further comprises at least one dye, as described elsewhere herein.

In some aspects, R¹ is C₁-C₁₀ alkyl, C₁-C₂ alkyl, C₁-C₃ alkyl, C₁-C₄ alkyl, C₁-C₅ alkyl, C₁-C₆ alkyl, C₁-C₈ alkyl, C₂-C₄ alkyl, C₂-C₆ alkyl, C₂-C₈ alkyl, C₂-C₁₀ alkyl, C₃-C₄ alkyl, C₃-C₆ alkyl, C₃-C₈ alkyl, C₃-C₁₀ alkyl, C₄-C₆ alkyl, C₄-C₈ alkyl, C₄-C₁₀ alkyl, C₆-C₈ alkyl, C₆-C₁₀ alkyl, C₈-C₁₀ alkyl, C₁ alkyl, C₂ alkyl, C₃ alkyl, C₄ alkyl, C₅ alkyl, C₆ alkyl, C₇ alkyl, C₈ alkyl, C₉ alkyl, or C₁₀ alkyl. In some aspects, R¹ is C₄ alkyl.

In some aspects, n is an integer from 10 to 10,000, such as 10-20, 10-30, 10-50, 10-100, 10-500, 10-1000, 10-5000, 100-500, 100-1000, 100-5000, 100-10000, 200-1000, 200-5000, 500-1000, 500-5000, 1000-5000, 1000-3000, 3000-5000, 5000-8000, or 5000-10000.

In some aspects, the polymer of formula (1) or salt thereof is racemic, comprises an excess of D amino acids, or comprises an excess of L amino acids. In this regard, the carbon marked with an asterisk (*) in the polymer of formula (1) is a stereocenter that, depending on its stereochemistry, can result in a D amino acid or an L amino acid. As a result, a plurality of polymers of formula (1) can comprise an excess of D amino acids, or can comprises an excess of L amino acids. In instances where the amount of D amino acids is the same as the amount of L amino acids, the plurality of polymers of formula (1) is a racemic mixture.

In some aspects, each amino acid in the polymer of formula (1) or salt thereof is a D amino acid or an L amino acid. In some aspects, some amino acids in the polymer of formula (1) or salt thereof are a D amino acid and some amino acids in the polymer of formula (1) or salt thereof are an L amino acid. In some aspects, the polymer of formula (1) or salt thereof is poly-D-lysine, optionally wherein n is 100-1000. In some aspects, the polymer of formula (1) or salt thereof is poly-L-lysine, optionally wherein n is 100-1000.

In some aspects, R² and R³ independently are terminating groups that can be the same or different. In some aspects, R² and R³ independently are hydrogen, C₁-C₃₀ alkyl, C₃-C₃₀ cycloalkyl, C₅-C₃₀ aryl, C₅-C₃₀ heteroaryl, C₁-C₃₀ acyl, C₂-C₃₀ alkenyl, C₂-C₃₀ alkynyl, or C₅-C₃₀ alkylaryl. In some aspects, R² and R³ independently can be a cation (e.g., sodium, lithium, potassium, magnesium, calcium, barium). In some aspects, R² and R³ independently are a C₁-C₃₀ alkyl (e.g., methyl, ethyl, propyl, butyl, pentyl, hexyl, and so forth, which can be linear or branched).

In some aspects, the polymer of formula (1) comprises an HX salt, wherein X is a halide. In some aspects, the halide is chloride, bromide, or iodide. In some aspects, the polymer of formula (1) comprises a mixture of HX salts.

In some aspects, the polymer of formula (1) is zwitterionic.

In some aspects, the photoactive device further comprises at least one dye. In some aspects, the photoactive device further comprises at least one dye capable of generating a photoexciton when illuminated with light having a wavelength of 530 nm or less, 400 nm to 450 nm, 425 nm, 350 nm to 500 nm, 390 nm to 440 nm, or 420 nm to 430 nm. Such wavelengths are sometimes referred to elsewhere herein as an “illumination wavelength.”

In some aspects, the at least one dye is soluble in water (e.g., distilled water). In some aspects, the at least one dye is in the form of a solution in or comprising distilled water.

In some aspects, the at least one dye comprises methylene blue, rhodamine red, rhodamine c, rhodamine 6g, rhodamine B, Safranin, Eosin, Basic Fuchsin, Acid Fuchsin, crystal violet, or any combination thereof. In some aspects, the at least one dye comprises methylene blue, which has the following chemical structure:

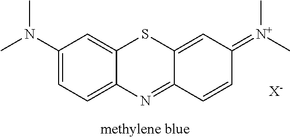

wherein X is any suitable counterion. X is not particularly limited and can include, for example, a halide (e.g., chloride, bromide, iodide), triflate, phosphate, nitrate, or tosylate. In some aspects, the counterion X is a chloride.

In some aspects, the at least one dye is present in the first layer, as a second layer positioned on the first layer, or a combination thereof.

In some aspects, the first layer has any suitable thickness, such as 10 nm to 2 μm, 10 nm to 100 nm, 10 nm to 250 nm, 10 nm to 500 nm, 10 nm to 1000 nm, 100 nm to 500 nm, 100 nm to 1000 nm, 500 nm to 1000 nm, 500 nm to 1.5 μm, 500 nm to 2 μm, 1 μm to 2 μm, or 1.5 μm to 2 μm.

In some aspects, the photoactive device further comprises a flexible substrate. In some aspects, the flexible substrate comprises polyimide, kapton, poly-vinylidene fluoride, a dielectric substrate, or any combination thereof. In some aspects, the dielectric substrate is not water soluble. In some aspects, the dielectric substrate comprises a gold interdigitated electrode on glass, titania, chromia, sapphire, or any combination thereof.

In some aspects, the photoactive device is configured as an organic photodetector, an organic photodiode, an organic photosensor, or an organic phototransistor.

In some aspects, the photoactive device exhibits lower current when illuminated with light having a wavelength of 530 nm or less, or 400 nm to 450 nm, or 425 nm (or any other illumination wavelength as disclosed elsewhere herein), compared to a current in an absence of any illumination, wherein the lower current is observed at at least one applied voltage in a range of −3 V to 3 V, and optionally wherein the lower current is less than five-tenths (e.g., less than four-tenths, less than three-tenths, less than two-tenths, less than one-tenth, or less than one-twentieth) of the current in the absence of any illumination at at least one applied voltage in a range of −3 V to 3 V. See, e.g., FIG. 2 and its associated descriptions elsewhere herein.

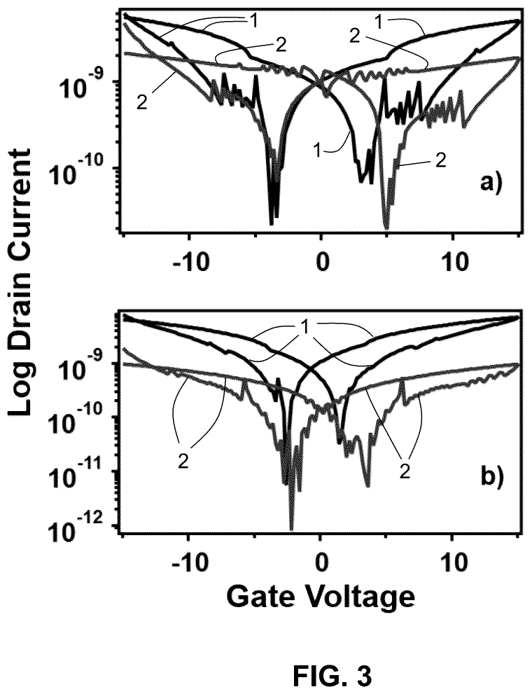

In some aspects, the photoactive device is configured as an organic phototransistor, and the organic phototransistor exhibits lower drain current when illuminated with light having a wavelength of 530 nm or less, or 400 nm to 450 nm, or 425 nm (or any other illumination wavelength as disclosed elsewhere herein), compared to a drain current in an absence of any illumination, wherein the lower drain current is observed at at least one gate voltage in a range of −15 V to 15 V. In some aspects, the organic phototransistor exhibits hysteresis over a gate voltage range of −15 V to 15 V. See, e.g., FIG. 3 and its associated descriptions elsewhere herein.

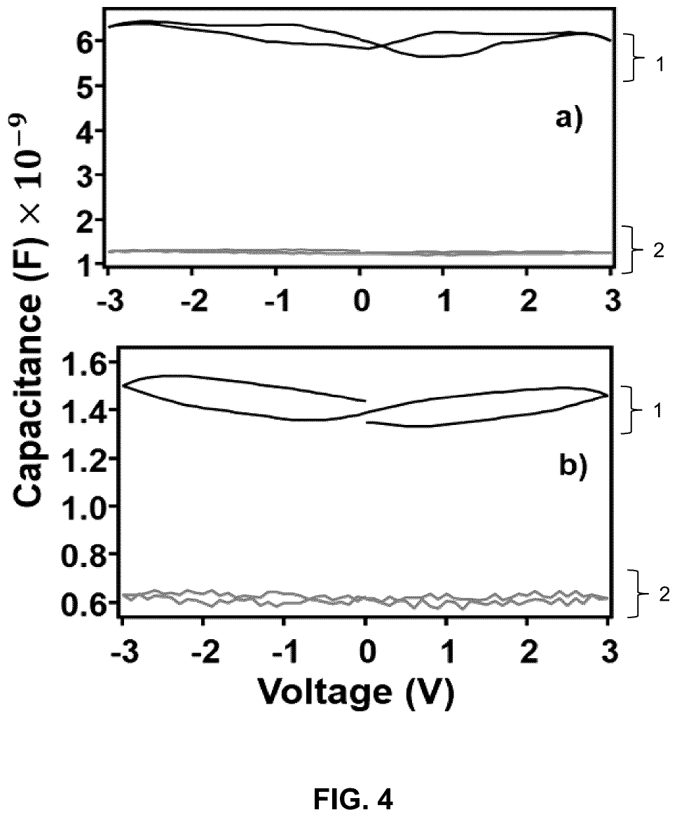

In some aspects, the photoactive device exhibits lower capacitance when illuminated with light having a wavelength of 530 nm or less, or 400 nm to 450 nm, or 425 nm (or any other illumination wavelength as disclosed elsewhere herein), compared to a capacitance in an absence of any illumination, wherein the lower capacitance is observed at at least one applied voltage in a range of −3 V to 3 V, and optionally wherein the lower capacitance is less than 80%, e.g., less than 70%, less than 60%, less than 50% (i.e., one-half), less than 40%, less than 30%, less than 20%, or less than 10% of the capacitance in the absence of any illumination at at least one applied voltage in a range of −3 V to 3 V. See, e.g., FIG. 4 and its associated descriptions elsewhere herein.

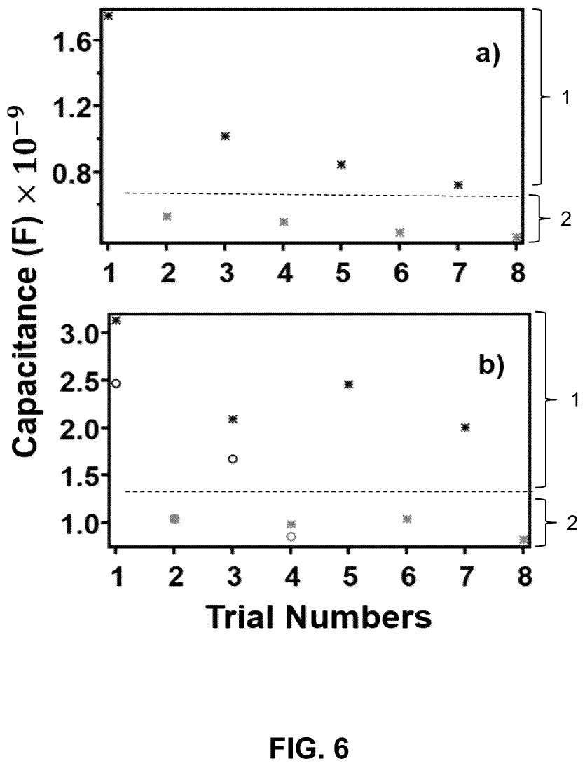

In some aspects, in a capacitance cycle test, the photoactive device has a capacitance ratio (c2/c1) for non-illuminated (c2) and illuminated (c1) states between each successive cycle of an eight cycle capacitance cycle test of at least 1.2, 1.2 to 5, 1.2 to 4, 1.2 to 3, 1.2 to 2, 1.3 to 5, 1.4 to 5, 1.5 to 5, 1.6 to 5, 1.7 to 5, 1.8 to 5, 1.9 to 5, 2 to 5, 1.2 to 2, 2 to 3, 3 to 4, or 4 to 5. As used herein, a “capacitance cycle test” is the test as described in Example 1 in relation to FIG. 6.

In some aspects, the photoactive device exhibits a non-zero current at zero bias both when illuminated with light having a wavelength of 530 nm or less, or 400 nm to 450 nm, or 425 nm (or any other illumination wavelength as disclosed elsewhere herein), and in an absence of any illumination.

In some aspects, the photoactive device exhibits hysteresis in a current-voltage curve or in a capacitance-voltage curve, or both, over an applied voltage range of −3 V to 3 V when illuminated with light having a wavelength of 530 nm or less, or 400 nm to 450 nm, or 425 nm (or any other illumination wavelength as disclosed herein), and in an absence of any illumination.

In some aspects, (1) when the photoactive device further comprises at least one dye (e.g., methylene blue) capable of generating a photoexciton when illuminated with light having a wavelength of 530 nm or less, or 400 nm to 450 nm, or 425 nm (or any other illumination wavelength as disclosed elsewhere herein), a charge carrier lifetime is higher under illumination with light having a wavelength of 530 nm or less, or 400 nm to 450 nm, or 425 nm, as compared to a charge carrier lifetime in an absence of any illumination; and (2) when an otherwise identical photoactive device does not contain the at least one dye, a charge carrier lifetime is lower under illumination with light having a wavelength of 530 nm or less, or 400 nm to 450 nm, or 425 nm (or any other illumination wavelength as disclosed elsewhere herein), as compared to a charge carrier lifetime in an absence of any illumination.

In some aspects, the photoactive device exhibits ferroelectric properties.

In some aspects, the photoactive device further comprising the at least one dye exhibits a larger difference in capacitance between illuminated and non-illuminated states as compared to a capacitance difference in an otherwise identical photoactive device that does not contain the at least one dye, wherein the illuminated state comprises illumination with light having a wavelength of 530 nm or less, or 400 nm to 450 nm, or 425 nm (or any other illumination wavelength as disclosed elsewhere herein), and the non-illuminated state comprises an absence of any illumination. In some aspects, a ratio (d1/d2) of the capacitance difference between non-illuminated and illuminated states for the photoactive device with (d1) and without (d2) the at least one dye is at least 1.1 to 5.

In some aspects, the photoactive device exhibits reversible change in capacitance when alternating between illuminated and non-illuminated states over at least at least three consecutive illumination and non-illumination cycles. Generally, the test as described in Example 1 in relation to FIG. 6 demonstrates how a reversible change in capacitance can be measured and confirmed.

In some aspects, disclosed is a method comprising illuminating a photoactive device disclosed elsewhere herein with light having a wavelength of 530 nm or less, or 400 nm to 450 nm, or 425 nm (or any other illumination wavelength as disclosed elsewhere herein). In some aspects, this method allows for use of the photoactive device in any suitable application including, for example, as photoactive devices, information storage devices, memory devices, semiconductor manufacturing, inverse phototransistors, dark sensors, thin film transistors (TFTs), organic TFTs, chemical sensors, biological sensors, detectors, sensors (e.g., dark and/or light sensors), or any combination thereof.

In some aspects, disclosed is a method of making a photoactive device, the method comprising depositing the first layer on a substrate. In one aspect, and solely as one as an illustration of how a photoactive device can be prepared, 5 mg of poly-D-lysine hydrobromide was dissolved it into 6.25 ml distilled water, then the poly-D-lysine solution was deposited on the substrate by drop casting method to make poly-D-lysine films. To make films of poly-D-lysine with methylene blue as an additive, 1 ml of the poly-D-lysine solution (made up of 5 mg of poly-D-lysine hydrobromide dissolved in 6.25 ml distilled water) was mixed with 20 μL of methylene blue solution (made up of 100±2 mg of methylene blue hydrate in 10 ml of distilled water) and the solution was deposited on the substrate by drop casting method to make films of poly-D-lysine with methylene blue. Of course, different components and amounts thereof can be utilized according to the same general method. Likely alternatives include a mixture of [Fe(Htrz)₂(trz)](BF₄) (trz-=1,2,4-triazolato) mixed with benzimidazole, which has a like organic dipolar character. Thin film deposition would be similar.

In some aspects, the depositing step comprises drop casting, screen printing, spin coating, or any combination thereof.

In some aspects, the depositing step comprises drop casting, and the drop casting comprises dissolving in a solvent (a) the polymer of formula (1) and (b) a dye capable of generating a photoexciton when illuminated with light having a wavelength of 530 nm or less, or 400 nm to 450 nm, or 425 nm (or any other illumination wavelength as disclosed elsewhere herein).

In some aspects, disclosed is a composition comprising a polymer of formula (1), and a dye capable of generating a photoexciton when illuminated with light having a wavelength of 530 nm or less, or 400 nm to 450 nm, or 425 nm (or any other illumination wavelength as disclosed elsewhere herein). In some aspects, the dye can be any dye disclosed elsewhere herein, such as methylene blue, rhodamine red, rhodamine c, rhodamine 6g, rhodamine B, Safranin, Eosin, Basic Fuchsin, Acid Fuchsin, crystal violet, or any combination thereof. In some aspects, the polymer of formula (1) is zwitterionic.

In some aspects, the composition is in the form of a layer, such as the first layer as described elsewhere herein. As such, the composition, whether in layer form or any other form, such as a powder, solid, solution, or suspension, can have any of the components and/or properties as disclosed elsewhere herein for the first layer, the polymer of formula (1), the at least one dye, and so forth. For example, in some aspects, the composition is in a form of a film (such as the first layer) having a thickness of 10 nm to 2 μm (or any other thickness of, e.g., the first layer as disclosed elsewhere herein).

The following examples further illustrate the invention but, of course, should not be construed as in any way limiting its scope.

### Example 1

This example demonstrates a voltage controlled bio-organic inverse phototransistor.

### Abstract

Thin films of poly-D-lysine acts as a polar organic thin films and are also light sensitive. The capacitance-voltage, current-voltage and transistor behavior were studied to gauge the photo-response of possible poly-D-lysine thin film devices both with and without methylene blue as an additive. Transistors fabricated from poly-D-lysine act as inverse phototransistors, i.e., the on-state current is greatest in the absence of illumination. The poly-D-lysine thin film capacitance decreases with illumination, but the transistor current also decreases, both with and without methylene blue as an additive. This suggests the unbinding of photo-exciton is significantly hindered in this system which is supported by the significant charge carrier lifetime for both poly-D-lysine films with and without methylene blue. The majority carrier in the transistor geometry appears to depend upon the gate voltage, in other words, the majority carrier depends on the polarization of the poly-D-lysine films both with and without methylene blue as an additive.

Keywords: poly-D-lysine, inverse organic phototransistor, polar organic thin films.

### Introduction

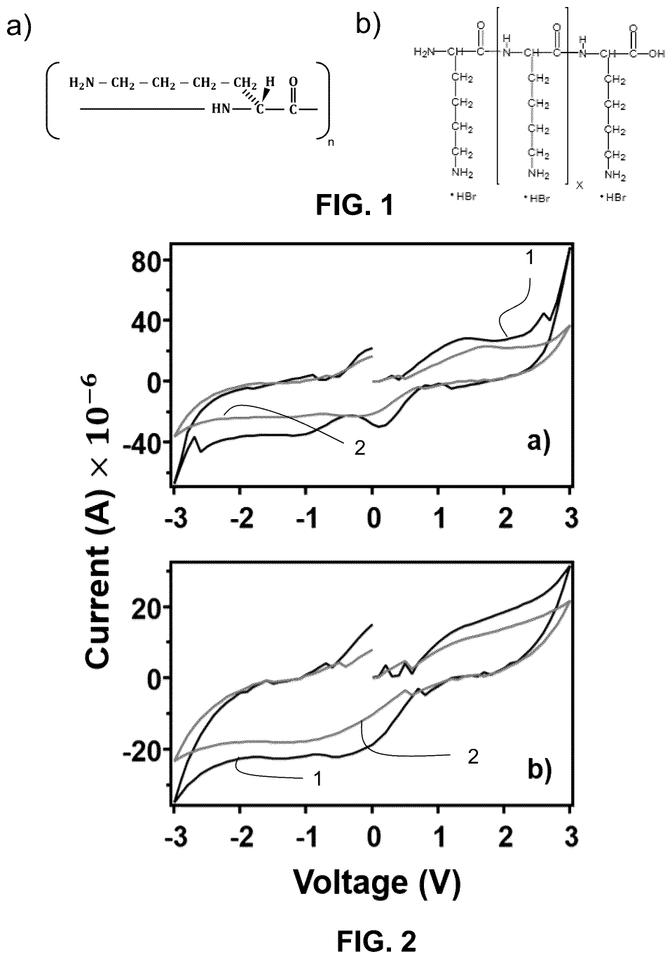

Phototransistors are common,^{[1]} however, phototransistor that have no photocurrent enhancement but rather a decrease in the source drain current, when exposed to light, are less common. Indeed, this sort of ‘inverse’ phototransistor is unusual. In recent years, organic photo-sensing devices are among the most attractive area of research due to its wide range of applications including organic photodetectors, organic photodiodes, organic photosensors and organic phototransistors.^{[2-6]} The low-cost fabrication method and ability to make changes in the properties of the material by just varying the chemical structure makes organic electronics very appealing.^{[7]} Polypeptides, i.e. polymers chains of amino acids connected via the peptide bond, are one of the widely studied areas in organic electronics.^{[8-10]} Poly-D-lysine is an amino acid biopolymer. The structure of poly-D-lysine is shown in FIG. 1.

Organic ferroelectrics have a dipole moment that can be aligned under an applied electric field giving rise to a spontaneous nonvolatile polarization.^{[11]} In an organic ferroelectric material, the reorientation of the dipoles, in the presence of an external electric field, generates a polarization hysteresis loop with voltage,^{[12]} first observed in a Rochelle salt.^{[13]} The phenomenon of ferroelectricity has also been observed in some amino acids and peptide nanotubes.^{[14-16]} The phenomena of ferroelectricity, requires static non-volatile alignment, but while polar molecules can be ferroelectric, antiferroelectric, pyroelectric and polar liquid phenomena are also possible. As shown here, poly-D-lysine can be added to the growing class of polar organic semiconductor. Furthermore, poly-D-lysine can be a useful component in a voltage controlled organic phototransistor structure.

### Experimental Section

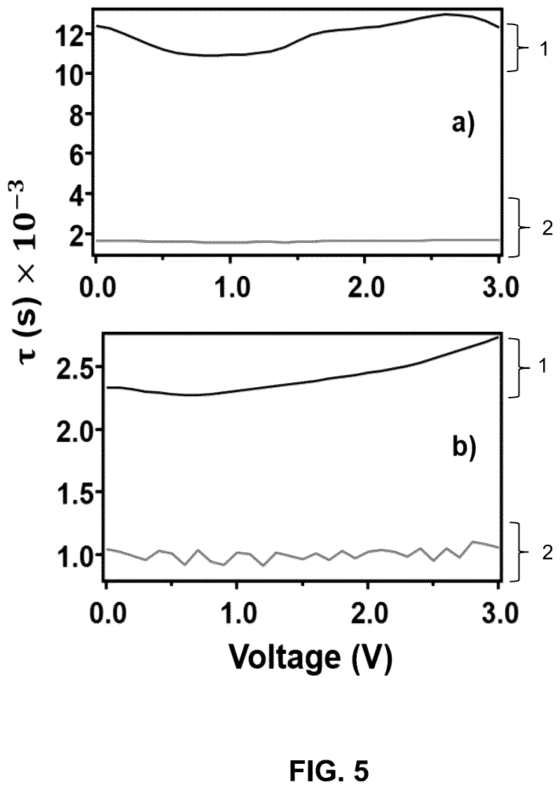

A solution of a) poly-D-lysine (Sigma-Aldrich), b) poly-D-lysine plus methylene blue (Sigma-Aldrich), in distilled water, was drop casted to make a film on several different interdigitated electrode system (MicruX Technologies and Metrohm DropSens) and on Organic Field effect Transistor (OFET) (Fraunhofer Institute for Photonic Microsystems IPMS). This demonstrated the reproducibility of the results as the measurements were similar and independent of the prepatterned electrodes used. The current-voltage and capacitance-voltage characteristics presented in FIG. 2, FIG. 4 and FIG. 5 were studied on interdigitated electrode system (Metrohm DropSens), and the data presented in FIG. 6 were studied on both interdigitated electrode system (MicruX Technologies and Metrohm DropSens) as specified in the FIG. 6 caption. The transistor characteristics presented in FIG. 3 were studied on an organic field effect transistor (OFET) by Fraunhofer Institute for Photonic Microsystems IPMS. 5 mg of poly-D-lysine hydrobromide was dissolved in 6.25 ml of distilled water to make a poly-D-lysine solution. The poly-D-lysine solution was deposited on the interdigitated electrodes by drop cast method to form a thin film for the current-voltage and capacitance-voltage measurements. For the transistor measurement, the poly-D-lysine solution was drop casted on OFET (Fraunhofer Institute for Photonic Microsystems IPMS) to make a thin film organic transistor.

To make films of poly-D-lysine with methylene blue as an additive, 1 ml of the poly-D-lysine solution (made up of 5 mg of poly-D-lysine hydrobromide dissolved in 6.25 ml distilled water) was mixed with 20 μL of methylene blue solution (made up of 100±2 mg of methylene blue hydrate in 10 ml of distilled water).

The films were left overnight wrapped in an aluminum foil after every drop casting to let it dry, and the measurements were done in the next day. As noted above, the current-voltage and capacitance-voltage (4200A-SCS parameter Analyzer) and the transistor (Cryogenic Lakeshore Probe Station) characteristics were measured. All the capacitance voltage measurements were done at the frequency of 10 kHz. The measurements in the light were taken after the films illuminated by a 425 nm wavelength 26 W Hg lamp for about 60-120 minutes. The films were left in dark and exposed to light for about 60-120 minutes interval in alternate cycles of dark and light. All the measurements were done at the room temperature.

Piezoelectric Force Microscopy (PFM) was performed on both the thin films of poly-D-lysine and poly-D-lysine plus methylene blue, but the conductance was too high to obtain a PFM signal.

FIG. 2 shows the photo-response of poly-D-lysine thin film devices.

Poly-D-lysine displays a conductance hysteresis loop, as a function of applied voltage, in both dark (curve 1) and light (curve 2), as seen in FIG. 2. Noteworthy is the fact that the current does not go to zero which indicates the presence of trapped charges, or a net polarization. The implication of the observed zero bias current is that there are trapped charges present, or a net polarization as there is a small conductance at zero voltage, for both dark and light. If one compares FIG. 2 a) to the I(V) characteristics of poly-D-lysine thin film with methylene blue as an additive, i.e., FIG. 2 b), the current in the latter case is smaller and decreases significantly with illumination.

As shown in FIG. 3, for poly-D-lysine as the semiconductor channel in the transistor geometry, both with and without methylene blue as an additive, the dark drain current at the dark (curve 1) is higher than the drain current with illumination (curve 2). For the poly-D-lysine with methylene blue as an additive, as seen in FIG. 3 b), the drain current is lower with illumination. This trend is consistent with the current versus voltage curves plotted in FIG. 2, except that there is significant hysteresis with gate voltage. As a result of the significant hysteresis, FIG. 3 indicates that thin film transistors of poly-D-lysine and poly-D-lysine plus methylene blue behaves as a both p-type and n-type transistor, i.e., bistable transistors.

The capacitance versus voltage, C(V) measurements at 10 kHz for poly-D-lysine thin films and poly-D-lysine with methylene blue as an additive are shown in FIGS. 4 a) and 4 b) respectively. While the current flow, with an applied voltage, is greater without illumination than under illumination, as seen in FIG. 2 and FIG. 3, it is evident that low conductance is actually associated with a smaller capacitance, as seen FIG. 4. Since there is both capacitance versus voltage and current versus voltage, this can be combined to estimate the drift carrier lifetime.

FIG. 5 shows the charge carrier lifetime versus voltage for both a) poly-D-lysine thin film and b) a poly-D-lysine thin film with methylene blue as an additive and the capacitance in both cases were measured at the frequency of 10 kHz. The charge carrier lifetime was calculated via^{[17,18]}:

$$τ = \frac{{( {( {( \frac{{C}_{D} ω \sqrt{2}}{{G}_{0}} )}^{2} + 1 )}^{2} - 1 )}^{1 / 2}}{ω}$$

Here, ‘τ’ is the charge carrier lifetime, ‘C_{D}’ is the capacitance having frequency dependency, ‘ω’ is the angular frequency defined as ω=2πf with frequency ‘f’ and ‘G₀’ is the conductance defined as

$${G}_{0} = \frac{dI}{dV}$$

with ‘V’ being the voltage applied and ‘I’ being the corresponding current.^{[17-18]}

As seen in FIG. 5, for poly-D-lysine thin film with and without methylene blue, the charge carrier lifetime is higher under no illumination than in the presence of illumination. The photoexcitons are unable to move and are thus more likely to recombine than unbind.

### Polar Organic Semiconductor:

The current at zero bias is non-zero (FIG. 2) yet poly-D-lysine thin films are not solar cell materials as this non-zero current occurs in both light and dark conditions. The presence of methylene blue in poly-D-lysine thin films, results in higher currents in the dark than with illumination. This too is not characteristic of a solar cell material. As the current is less under illumination, especially in the transistor geometry as seen in FIG. 3, this further indicates that poly-D-lysine, with and without methylene blue as an additive, is not intrinsically a solar cell material. It is clear that the photoexcitons are bound charges low mobility and the electron hole pair does not unbind and are responsible for the decrease in current with illumination as seen in FIG. 2 and FIG. 3.

The capacitance exhibits hysteresis with voltage, in the absence of illumination as seen in FIG. 4. The butterfly loop hysteresis of the C(V) characteristics is also clearly an indication of the material being polar as the extent of polarization would change the dielectric capacitance. The occurrence of polarization switching corresponding to the applied positive and negative biases is observed the transistor characteristics, as a function of gate voltage in both FIGS. 3 a) and 3 b). This type of current hysteresis is also common in ferroelectric materials.^{[19-22]}

Clearly, the poly-D-lysine films, with and without methylene blue as an additive, are p-type with one polarization and then after applying sufficient voltage, the films become n-type, associated with the opposite polarization as seen in the transistor characteristics of FIG. 3. The majority carriers can change from holes to electrons as a result of changing polarization, controlled by the gate voltage. The maximum capacitance value at positive and negative bias corresponds to the coercive voltage (+V_{c}) and (−V_{c}) in the butterfly C(V) hysteresis loop (FIG. 4) and in the transistor characteristics seen in FIG. 3. The flat shape of C(V) loop around zero voltage has also been observed in thin ferroelectric films and were attributed to the trap states due to the electrode interface effect.^{[23]}

Clearly polar, and while not proven because of the changing majority carrier, ferroelectric seems implicated but antiferroelectric is not completely excluded by the data presented for both poly-D-lysine films, with and without methylene blue as an additive.

### State Switching:

The results presented in FIG. 3 illustrates that the poly-D-lysine with methylene blue can be used to make a phototransistor that is in the “off state” when illuminated by light and in the “on state” when in dark. The fact that poly-D-lysine can be used to make a photoactive transistor with lower conductance under illumination than in the dark is unusual.

This photoactive response is true not only of transistor devices but also of the capacitive device structure. As shown in FIG. 4, for a given range of voltage, the value of capacitance is higher when the light is turned off i.e., at dark (curve 1) in comparison to when the light is turned on (curve 2). High capacitance is consistent with the significant dielectric properties of a polar material in the single polarization state.

The decrease in capacitance, under illumination, for poly-D-lysine film with and without methylene blue (FIG. 4), is difficult to reconcile with the decrease in conductance (FIG. 2 and FIG. 3), but photo excitations may decrease the net polarization. When the light is turned on, although the presence of light increases the number of photoexcitons, the photoexcitons lead to depolarization hence the capacitance is low (curve 2, FIG. 4). Thus poly-D-lysine, with and without methylene blue as an additive, remains dielectric under illumination but carrier lifetime and possibly the carrier concentration is suppressed. Similar trends are seen for the poly-D-lysine film with and without methylene blue although the drift carrier lifetime is higher in poly-D-lysine film without methylene blue than with methylene blue as an additive.

FIG. 6 shows the capacitance values measured at alternate cycles of dark and light. The films were left in dark and exposed to light for about 60-120 minutes interval in alternate cycles and the capacitance value for the range of −3 V to +3 V was recorded. Each point in FIG. 6 corresponds to the capacitance value at 3 V, however, the capacitance value in FIG. 6 b) on Metrohm DropSens electrodes was scaled with respect to the capacitance value on MicruX electrodes. It is evident from FIG. 6 a) that the capacitance is higher for dark (dots labeled “1”) than light (dots labeled “2”). As seen in FIG. 6 b), we performed the capacitance measurements on two different electrode surface and scaled it as mentioned in the caption of FIG. 6, the results of which also demonstrates the capacitance is higher in dark than light. This behavior of poly D lysine provides a valid reason for why the poly D lysine can be used as an inverse phototransistor.

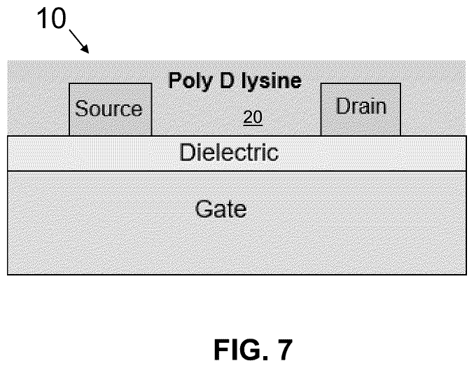

A schematic of a photoactive device structure 10 according to an embodiment is shown in FIG. 7. Photoactive device 10 includes a photoactive layer 20 (e.g., any photoactive layer material as described herein) having two electrodes (e.g., source and drain) as shown. A substrate may be used to assist with fabrication of the device and/or for structural robustness of device 10, but is not necessary for operation of device 10. In one embodiment, the source includes a thin layer of a transparent or semi-transparent conductive material (e.g., 25 nm Au layer). Useful source materials include any transparent or semi-transparent conductive or semi-conductive material, such as metals or metal films, conductive polymers, carbon nanotubes, graphene, a network of metal nanowires, organic or inorganic transparent conducting films (TCFs), transparent conducting oxides (TCOs), etc. Specific examples of source materials include gold (Au), silver (Ag), titanium (Ti), indium tin oxide (ITO), copper (Cu), carbon nanotubes, graphene, aluminum (Al), chromium (Cr), lead (Pb), platinum (Pt), and PEDOT:PSS. Known deposition or thermal evaporation techniques may be used to form the drain. The drain also includes a thin layer of conductive or semi-conductive material. Useful drain materials include the same materials as may be used for the source. Specific examples of drain materials include gallium (Ga), gold (Au), silver (Ag), tin titanium (Ti), indium tin oxide (ITO), indium (In), copper (Cu), carbon nanotubes, graphene, aluminum (Al), chromium (Cr), lead (Pb), platinum (Pt), and PEDOT:PSS. Known deposition or thermal evaporation techniques may be used to form the gate, dielectric and any other desired layers. The substrate provides structural stability and may include glass, polymer, dielectric, semiconductor materials, etc.

There is sufficient example of an organic ferroelectric like the variations of polyvinylidene fluoride (including polyvinylidene fluoride trifluroethylene: PVDF-TrFE),^{[24,25]} croconic acid,^{[26]} thiourea,^{[27,28]} tricyclohexylmethanol (TCHM),^{[29]} diazabicyclo[2.2.2]octane (dabco) salts,^{[30]} hydrogen-bonding chains of 3-hydroxyphenalenone (3-HPLN),[^{31]} 1,6-bis(2,4-dinitrophenoxy)-2,4-hexadiyne,^{[32-34]} and amino acids like glycine.^{[14,16]} Information storage is one of the most important aspects of any memory device and the polarization response observed in ferroelectric materials are suitable for memory applications.^{[35]} The common examples of memory devices based on organic ferroelectricity are ferroelectric capacitors^{[36]} and ferroelectric field effect transistors.^{[37]}

Poly-D-lysine in combination with methylene blue can be used to fabricate a phototransistor which is the combination of both p-type and n-type and is off state when illuminated and the on state when not illuminated, in other words, an inverse phototransistor. The presence of methylene blue in poly-D-lysine thin film enhances the inverse phototransistor effect of poly-D-lysine. Poly-D-lysine thin film could be an ideal sensor because it operates in the reverse sense of other photodiodes and phototransistors. The low cost of materials and trivial deposition method makes it also very attractive as this potentially reduces fabrication costs. Because these organic thin films are easily fabricated, and compatible with flexible substrates, there is the potential here for low-cost organic inverse phototransistors. This study provides a route for creating an organic inverse phototransistor that is cost effective and easy to fabricate.

### REFERENCES

[1] H. Yoo, S. Lee, S. Jung, S. M. Rho, B. H. Kang, H. J. Kim, Adv. Mater. 2021, 2006091
[2] J. Huang, J. Lee, J. Vollbrecht, V. V. Brus, A. L. Dixon, D. X. Cao, Z. Zhu, Z. Du, H. Wang, K. Cho, G. C. Bazan, T. Q. Nguyen, Adv. Mater. 2020, 32, 1906027.
[3] Y. L. Wu, K. Fukuda, T. Yokota, T. Someya, Adv. Mater. 2019, 31, 1903687.
[4] C. Wang, X. Zhang, W. Hu, Chem. Soc. Rev. 2020, 49, 653.
[5] H. Wang, H. Liu, Q. Zhao, Z. Ni, Y. Zou, J. Yang, L. Wang, Y. Sun, Y. Guo, W. Hu, Y. Liu, Adv. Mater. 2017, 29, 1701772.
[6] Z. Lin, Q. Chen, Y. Yan, Y. Liu, E. Li, W. Yu, H. Chen, T. Guo, IEEE Electron Device Lett. 2021, 42, 1358.
[7] S. R. Forrest, M. E. Thompson, Chem. Rev. 2007, 107, 923.
[8] B. D. Wall, A. E. Zacca, A. M. Sanders, W. L. Wilson, A. L. Ferguson, J. D. Tovar, Langmuir 2014, 30, 5946.
[9] S. Khanra, T. Cipriano, T. Lam, T. A. White, E. E. Fileti, W. A. Alves, S. Guha, Adv. Mater. Interfaces 2015, 2, 1500265.
[10] H. A. M. Ardona, J. D. Tovar, Bioconjug. Chem. 2015, 26, 2290.
[11] K. Asadi, D. M. de Leeuw, B. de Boer, and P. W. M. Blom, Nat. Mater. 2008, 7, 547-550.
[12] V. S. Bystrov, E. Paramonova, I. Bdikin, S. Kopyl, A. Heredia, R. C. Pullar, A. L. Kholkin, Ferroelectrics 2012, 440, 3.
[13] J. Valasek, Phys. Rev. 1921, 17, 475.
[14] P. Hu, S. Hu, Y. Huang, J. R. Reimers, A. M. Rappe, Y. Li, A. Stroppa, W. Ren, J. Phys. Chem. Lett. 2019, 10, 1319.
[15] I. Bdikin, V. Bystrov, S. Kopyl, R. P. G. Lopes, I. Delgadillo, J. Gracio, E. Mishina, A. Sigov, A. L. Kholkin, Appl. Phys. Lett. 2012, 100, 043702.
[16] A. Heredia, V. Meunier, I. K. Bdikin, J. Gracio, N. Balke, S. Jesse, A. Tselev, P. K. Agarwal, B. G. Sumpter, S. V. Kalinin, A. L. Kholkin, Adv. Funct. Mater. 2012, 22, 2996.
[17] Z. G. Marzouk, A. Dhingra, Y. Burak, V. Adamiv, I. Teslyuk, P. A. Dowben, Mater. Lett. 2021, 297, 129978.
[18] C. C. Ilie, F. Guzman, B. L. Swanson, I. R. Evans, P. S. Costa, J. D. Teeter, M. Shekhirev, N. Benker, S. Sikich, A. Enders, P. A. Dowben, A. Sinitskii, A. J. Yost, J. Phys. Condens. Matter 2018, 30, 18LT02.
[19] M. H. Amiri, J. Heidler, K. Mullen, K. Asadi, ACS Appl. Electron. Mater. 2020, 2, 2.
[20] M. M. Hasan, C. W. Ahn, T. H. Kim, J. Jang, Appl. Phys. Lett. 2021, 118.
[21] S. Moon, J. Shin, and C. Shin, Electronics 2020, 9, 704.
[22] S. Das, J. Appenzeller, Nano Lett. 2011, 11, 4003.
[23] M. Vehkamäki, T. Hatanpää, M. Kemell, M. Ritala, M. Leskelä, Chem. Mater. 2006, 18, 3883.
[24] L. M. Blinov, V. M. Fridkin, S. P. Palto, A. V Bune, P. A. Dowben, S. Ducharme, Physics-Uspekhi 2000, 43, 243.
[25] S. Horiuchi, Y. Tokura, Nature materials 2008, 7, 357-366.
[26] X. Jiang, H. Lu, Y. Yin, X. Zhang, X. Wang, L. Yu, Z. Ahmadi, P. S. Costa, A. D. Dichiara, X. Cheng, A. Gruverman, A. Enders, X. Xu, Appl. Phys. Lett. 2016, 109.
[27] G. J. Goldsmith, J. G. White, J. Chem. Phys. 1959, 31, 1175.
[28] A. L. Solomon, Physical Review, 1956, 104, 1191.
[29] Y. Yamamura, H. Saitoh, M. Sumita, K. Saito, J. Phys. Condens. Matter 2007, 19, 176219.
[30] D. W. Fu, J. X. Gao, W. H. He, X. Q. Huang, Y. H. Liu, Y. Ai, Angew. Chemie—Int. Ed. 2020, 59, 17477.
[31] S. Horiuchi, R. Kumai, Y. Tokura, Adv. Mater. 2011, 23, 2098.
[32] P. Gruner-Bauer, E. Dormann, J. Phys. Condens. Matter 1992, 4, 5599.
[33] H. Winter, E. Dormann, M. Bertault, L. Toupet, Physical Review B 1992, 46, 8057.
[34] G. Nemec, E. Dormann, J. Phys. Condens. Matter 1994, 6, 1417.
[35] R. C. G. Naber, K. Asadi, P. W. M. Blom, D. M. De Leeuw, B. De Boer, Adv. Mater. 2010, 22, 933.
[36] T. Lenz, D. Zhao, G. Richardson, I. Katsouras, K. Asadi, G. Glaßer, S. T. Zimmermann, N. Stingelin, W. S. C. Roelofs, M. Kemerink, P. W. M. Blom, D. M. De Leeuw, Phys. Status Solidi Appl. Mater. Sci. 2015, 212, 2124.
[37] T. Kanashima, Y. Katsura, M. Okuyama, Jpn. J. Appl. Phys. 2014, 53, 04ED11.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A photoactive device, comprising:
a first layer comprising a polymer of formula (1): 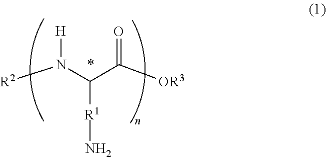
or a salt thereof;
wherein:
R¹ is a single bond or an optionally substituted C₁-C₁₀ alkyl group;
R² and R³ independently are terminating groups that can be the same or different; and
n is an integer from 10 to 10,000.

2. The photoactive device of claim 1, wherein the polymer of formula (1) or salt thereof is racemic, comprises an excess of D amino acids, or comprises an excess of L amino acids.

3. The photoactive device of claim 1, wherein each amino acid in the polymer of formula (1) or salt thereof is a D amino acid or an L amino acid.

4. The photoactive device of claim 1, wherein the polymer of formula (1) or salt thereof is poly-D-lysine.

5. The photoactive device of claim 1, wherein R¹ is a C₃-C₆ alkyl group.

6. The photoactive device of claim 1, wherein n is an integer from 100 to 1,000.

7. The photoactive device of claim 1, wherein R² and R³ independently are hydrogen, C₁-C₃₀ alkyl, C₃-C₃₀ cycloalkyl, C₅-C₃₀ aryl, C₅-C₃₀ heteroaryl, C₁-C₃₀ acyl, C₂-C₃₀ alkenyl, C₂-C₃₀ alkynyl, or C₅-C₃₀ alkylaryl.

8. The photoactive device of claim 1, wherein the polymer of formula (1) comprises an HX salt, wherein X is a halide.

9. The photoactive device of claim 1, wherein the polymer of formula (1) is zwitterionic.

10. The photoactive device of claim 1, further comprising at least one dye capable of generating a photoexciton when illuminated with light having a wavelength of 530 nm or less, or 400 nm to 450 nm, or 425 nm.

11. The photoactive device of claim 10, wherein the at least one dye is soluble in water, or wherein the at least one dye is in the form of a solution in distilled water.

12. (canceled)

13. The photoactive device of claim 10, wherein the at least one dye is present in the first layer or as a second layer positioned on the first layer.

14. The photoactive device of claim 1, wherein the first layer has a thickness of 10 nm to 2 μm.

15. The photoactive device of claim 1, further comprising a flexible substrate.

16. (canceled)

17. (canceled)

18. The photoactive device of claim 1, wherein the photoactive device is configured as an organic photodetector, an organic photodiode, an organic photosensor, or an organic phototransistor.

19.-30. (canceled)

31. A method, comprising:
illuminating the photoactive device of claim 1 with light having a wavelength of 530 nm or less, or 400 nm to 450 nm, or 425 nm.

32. A method of making the photoactive device of claim 1, the method comprising:
depositing the first layer on a substrate, wherein the depositing step comprises drop casting, screen printing, spin coating, or any combination thereof.

33. (canceled)

34. The method of claim 32, wherein the depositing step comprises drop casting, and the drop casting comprises dissolving in a solvent (a) the polymer of formula (1) and (b) a dye capable of generating a photoexciton when illuminated with light having a wavelength of 530 nm or less, or 400 nm to 450 nm, or 425 nm.

35. A composition, comprising:
the polymer of claim 1; and
a dye capable of generating a photoexciton when illuminated with light having a wavelength of 530 nm or less, or 400 nm to 450 nm, or 425 nm.

36. The composition of claim 35,
wherein the polymer is zwitterionic.

37. (canceled)

38. (canceled)
